(19) United States
(12) Patent Application Publication
(10) Pub. No.: US 2014/0191210 A1
(43) Pub. Date: Jul. 10, 2014

(54) ORGANIC LIGHT-EMITTING DIODE DEVICE

(71) Applicant: Ultimate Image Corporation, Miaoli County (TW)

(72) Inventor: Chih-Feng SUNG, Miaoli County (TW)

(73) Assignee: Ultimate Image Corporation, Miaoli County (TW)

(21) Appl. No.: 14/088,547

(22) Filed: Nov. 25, 2013

(30) Foreign Application Priority Data
Jan. 9, 2013 (TW) 102100755

(51) Int. Cl. H01L 51/52

(52) U.S. Cl. CPC H01L 51/5209
USPC 257/40

(57) ABSTRACT

An organic light-emitting diode device includes a substrate, a patterned anode layer, an organic semiconductor layer and a cathode layer. The patterned anode layer is disposed on the substrate. The organic semiconductor layer is disposed to cover an upper surface and sidewalls of the patterned anode layer and the substrate, wherein a thickness of the organic semiconductor layer is greater than three times of that of the patterned anode layer. The cathode layer is disposed to cover the organic semiconductor layer.

### FIELD OF THE INVENTION

The invention relates to an organic light-emitting diode (OLED) device, and more particularly to an OLED device used in a lighting apparatus.

### BACKGROUND OF THE INVENTION

In a process for manufacturing a conventional organic light-emitting diode (OLED) device used in a display, a bank structure formed by an organic macromolecule layer is generally used to define a specific light-emitting region so as to prevent problems such as leakage or short-circuit.

As shown in FIG. 1, a recess 108 is formed between two adjacent bank structures 106, and an organic semiconductor layer 110 is formed in the recess 108 and between a first transparent electrode 104 and a second electrode 114. The first transparent electrode 104 and the second electrode 114 are separated from each other by the bank structure 106 and the organic semiconductor layer 110. In this way, short-circuit can be prevented. However, the presence of the bank structure 106 reduces a light-emitting area and an aperture ratio. Moreover, a process for manufacturing the bank structure 106 also relatively increases a manufacturing cost.

In view of this, the inventor considered defects in the manufacturing process and the structure of the conventional OLED device used in a display, and provides an OLED device without a bank structure. The OLED device can be used in a lighting apparatus. A light-emitting area of an element and an aperture ratio are increased, and leakage and short-circuit problems in the conventional OLED device are solved.

### SUMMARY OF THE INVENTION

The invention provides an organic light-emitting diode (OLED) device, which can be used in a lighting apparatus. According to the invention, the manufacturing process is simplified, the light-emitting area of the element is increased, the aperture ratio is improved, and the leakage and short-circuit is prevented.

To achieve above and other advantages, an OLED device is provided according to an embodiment of the invention. The OLED device includes a substrate, a patterned anode layer, an organic semiconductor layer and a cathode layer. The patterned anode layer is disposed on the substrate. The organic semiconductor layer is disposed to cover an upper surface and sidewalls of the patterned anode layer and the substrate, wherein a thickness of the organic semiconductor layer is greater than three times of that of the patterned anode layer. The cathode layer is disposed to cover the organic semiconductor layer.

In an embodiment of the invention, the patterned anode layer includes a first anode layer and a second anode layer disposed on the substrate side by side, and the organic semiconductor layer also covers a substrate surface between the first anode layer and the second anode layer.

In an embodiment of the invention, an interval between the first anode layer and the second anode layer is greater than 3 μm.

In an embodiment of the invention, an interval between the first anode layer and the second anode layer is between 3˜10 μm.

In an embodiment of the invention, a thickness of the organic semiconductor layer is between 150˜300 nm, and a thickness of the patterned anode layer is between 40˜60 nm.

In an embodiment of the invention, the OLED device is used in a lighting apparatus.

In an embodiment of the invention, the organic semiconductor layer includes at least a hole injection layer, a hole transport layer, a light-emitting layer, an electron transport layer and an electron injection layer.

In an embodiment of the invention, the patterned anode layer is a transparent conductive layer.

In an embodiment of the invention, the substrate is a transparent substrate.

In summary, according to the invention, a step coverage of the organic semiconductor layer is increased by designing a relative thickness ratio of the anode layer and the organic semiconductor layer. In this way, the edge leakage problem can be prevented and a conventional bank structure in an OLED device can be omitted. This improves an element yield rate and increases a light-emitting area of the OLED device. Moreover, according to the invention, short-circuit caused by an impurity adhered to the substrate in the manufacturing process can be prevented by designing an interval between two adjacent anode layers. Therefore, according to the invention, not only the process for manufacturing an OLED device used in a lighting apparatus can be simplified, but also the element yield rate can be increased, and a light-emitting efficiency of an OLED lighting apparatus can be improved.

### BRIEF DESCRIPTION OF THE DRAWINGS

The invention will become more readily apparent to those ordinarily skilled in art after reviewing the following detailed description and accompanying drawings, in which:

FIG. 1 is a schematic diagram showing a conventional organic light-emitting diode (OLED) device with a bank structure;

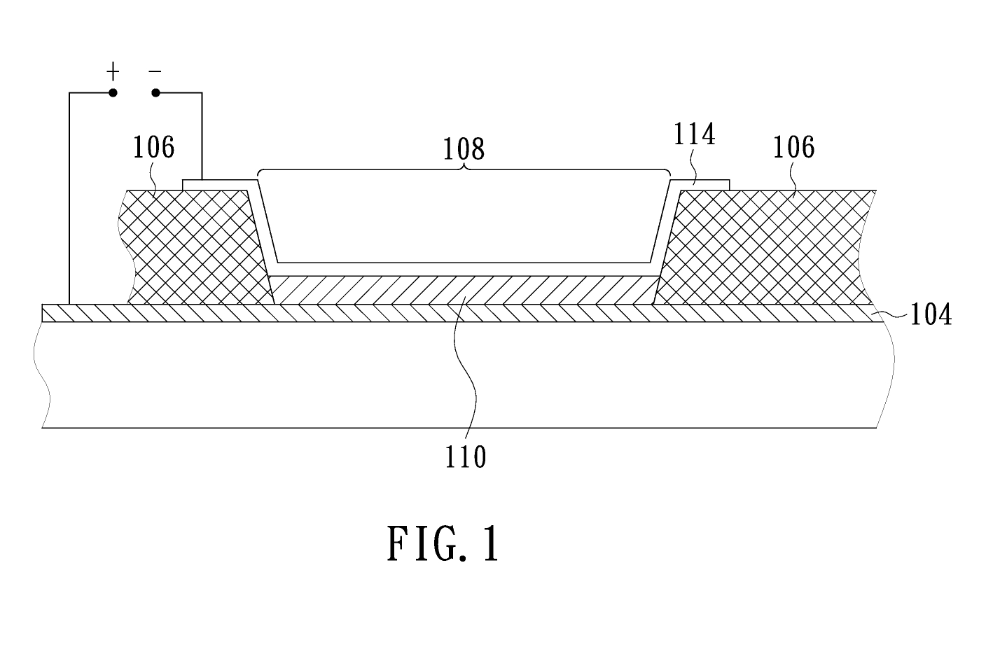

FIG. 2 is a schematic diagram showing an OLED device according to an embodiment of the invention;

FIG. 3A is a schematic diagram showing an OLED device according to another embodiment of the invention;

FIG. 3B is a cross-section schematic diagram showing an impurity adhered to the substrate according to the another embodiment of the invention;

FIG. 4A is a schematic diagram showing an OLED device according to another embodiment of the invention; and

FIG. 4B is a top view showing the OLED device shown in FIG. 4A.

### DETAILED DESCRIPTION OF EMBODIMENTS

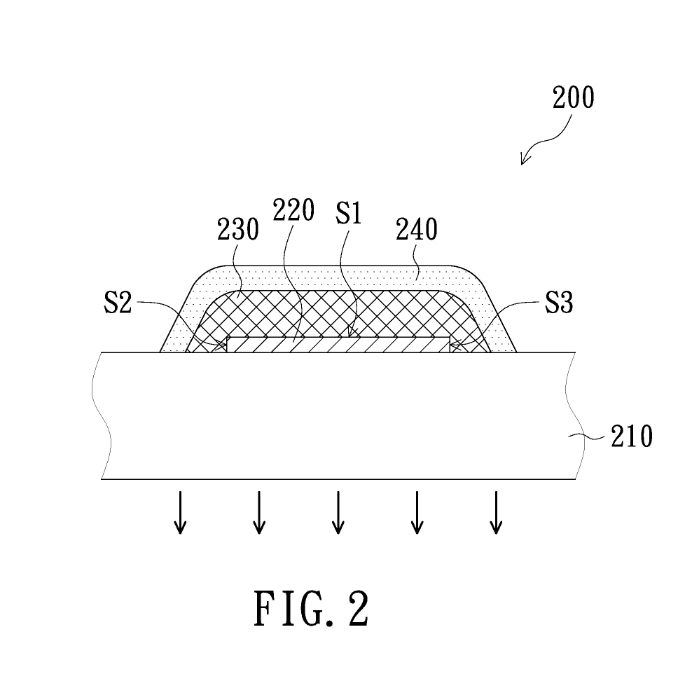

FIG. 2 is a schematic diagram showing an organic light-emitting diode (OLED) device 200 according to an embodiment of the invention. Referring to FIG. 2, the OLED device 200 includes a substrate 210, a patterned anode layer 220, an organic semiconductor layer 230 and a cathode layer 240. The OLED device 200 can be used in a lighting apparatus. The patterned anode layer 220 is disposed on the substrate 210. The organic semiconductor layer 230 is disposed to cover an upper surface 51 and sidewalls S2, S3 of the patterned anode layer 220 and the substrate 210. The cathode layer 240 is disposed to cover the organic semiconductor layer 230. Moreover, the substrate 210 may be a transparent substrate, for example, a transparent conductive glass or a flexible resin substrate. The patterned anode layer 220 is a transparent conductive layer that is generally composed of a transparent conductive oxide material including, but not limited to, indium tin oxide (ITO). The cathode layer 240 is generally composed of a nontransparent metal conductive layer.

The thickness of the organic semiconductor layer 230 is greater than three times of that of the patterned anode layer 220. The thickness of the organic semiconductor layer 230 is, for example, between 150˜300 nm, and the thickness of the patterned anode layer 220 is, for example, between 40˜60 nm. Moreover, the organic semiconductor layer 230 includes at least a hole injection layer, a hole transport layer, a light-emitting layer, an electron transport layer and an electron injection layer (not shown). When the step coverage of the organic semiconductor layer 230 is relatively increased; that is, when the thickness of the organic semiconductor layer 230 is greater than three times of that of the patterned anode layer 220, the thickness of the organic semiconductor layer 230 is sufficient for withstanding a relatively high electric field at a tip edge of the patterned anode layer 220, thereby preventing an edge leakage problem. Moreover, in the OLED 200 of the invention, a conventional bank structure for defining a light-emitting region is omitted; that is, the organic semiconductor layer 230 for emitting light is disposed to cover the entire upper surface of the patterned anode layer 220. This can help to improve an aperture ratio of the OLED device.

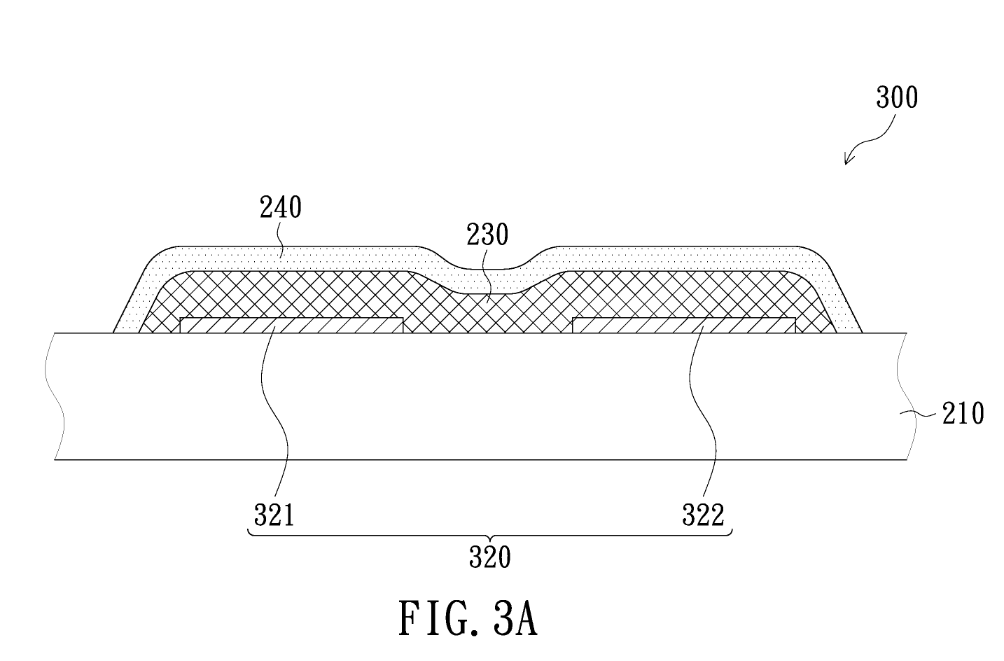

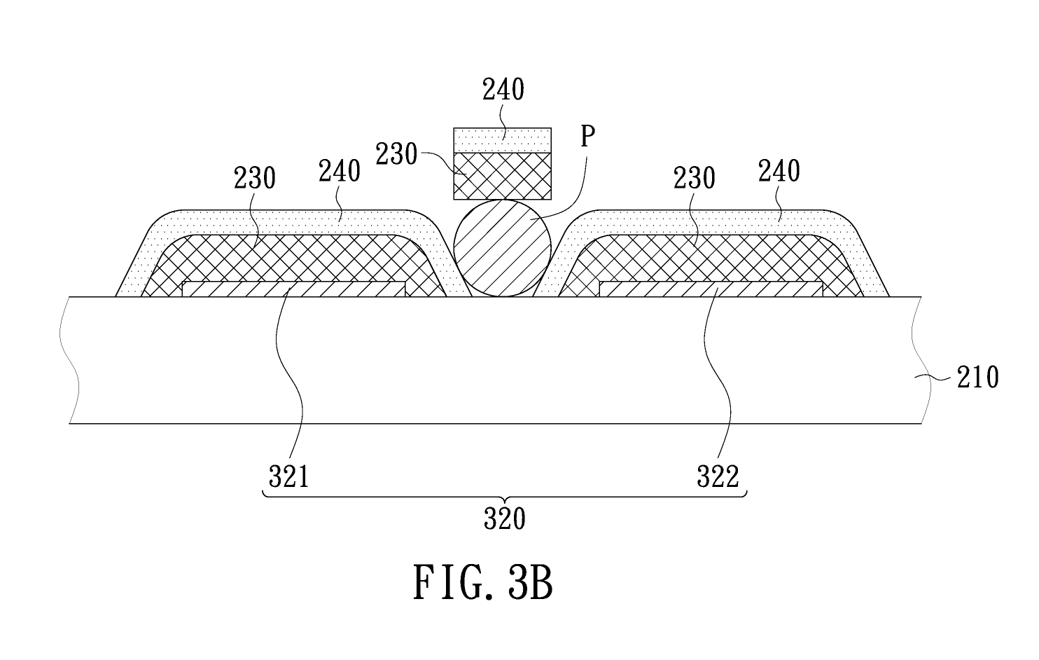

FIG. 3A is a cross-section diagram showing an OLED device 300 according to another embodiment of the invention. Referring to FIG. 3A, the OLED device 300 of the invention includes a substrate 210, a patterned anode layer 320, an organic semiconductor layer 230 and a cathode layer 240. The OLED device 300 can be used in a lighting apparatus. Different from the patterned anode layer 220, the patterned anode layer 320 includes, for example, a first anode layer 321 and a second anode layer 322. The first anode layer 321 and the second anode layer 322 are separated from each other and are disposed on the substrate 210 side by side. The material of the patterned anode layer 320 is the same as that of the patterned anode layer 220 and will not be repeated here.

Moreover, the organic semiconductor layer 230 is disposed to cover not only upper surfaces and sidewalls of the first anode layer 321 and the second anode layer 322, but also the surface of the substrate 210 between the first anode layer 321 and the second anode layer 322. That is, in the OLED 300 of the invention, a conventional bank structure between two light-emitting regions formed around the first anode layer 321 and the second anode layer 322 is omitted. This can help to improve an aperture ratio of the OLED device. However, it should be considered that in the process for manufacturing the patterned anode layer 320, inevitably there will be impurities adhering to the substrate 210 between the first anode layer 321 and the second anode layer 322. If an impurity is just stuck in the edges of the first anode layer 321 and the second anode layer 322, the first anode layer 321 and the second anode layer 322 cannot be completely covered by the organic semiconductor layer 230 in subsequent manufacturing processes. Thus, the cathode layer 240 formed subsequently may contact the first anode layer 321 and/or the second anode layer 322 directly, this leads to short-circuit. Therefore, in a preferable embodiment, an interval between the first anode layer 321 and the second anode layer 322 is, for example, greater than 3 μm. This can prevent short-circuit caused by the adhesion of impurities with diameters less than 1 μm. In another preferable embodiment, an interval between the first anode layer 321 and the second anode layer 322 is, for example, about 10 μm. This can prevent short-circuit caused by the adhesion of impurities with diameters less than 8 μm. Therefore, when the interval between the first anode layer 321 and the second anode layer 322 is between 3˜10 μm, the above-mentioned problem can be prevented. However, the interval between the first anode layer 321 and the second anode layer 322 can be adjusted according to requirements of the manufacturing process, and is not limited to the above-mentioned range.

FIG. 3B is a cross-section schematic diagram showing an impurity adhered to the substrate as mentioned above. In FIG. 3B, the interval between the first anode layer 321 and the second anode layer 322 is, for example, about 5 μm. Therefore, when an impurity P with a diameter of 2 μm adheres to the substrate 210 between the first anode layer 321 and the second anode layer 322, the interval between the first anode layer 321 and the second anode layer 322 is sufficient for the organic semiconductor layer 230 to completely cover the first anode layer 321 and the second anode layer 322, respectively. Therefore, short-circuit caused by the cathode layer 240 directly contacting with the first anode layer 321 and/or the second anode layer 322 can be prevented.

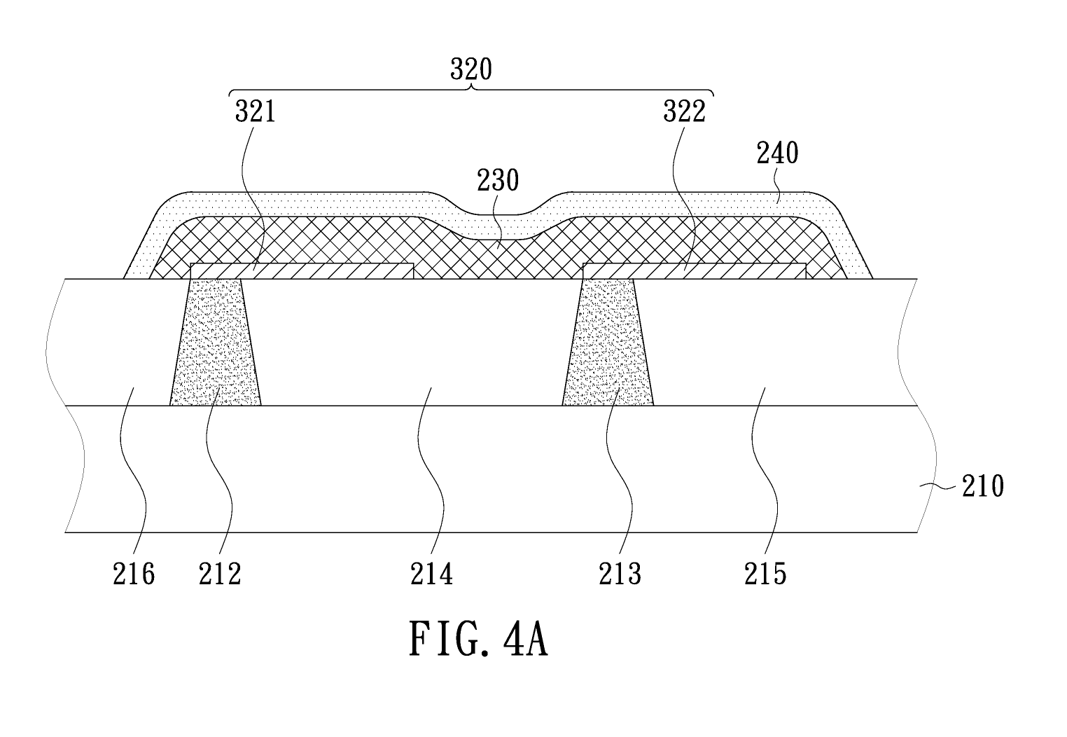

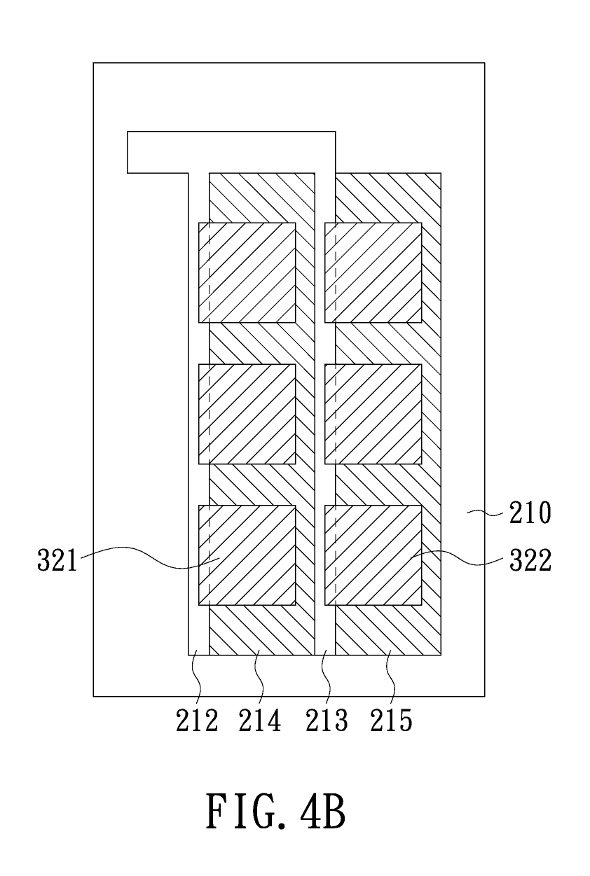

In another embodiment of the invention, referring to FIG. 4A, a plurality of metal shunt electrodes 212, 213 and an insulating layer 214 are formed on the substrate 210, wherein the insulating layer 214 is disposed between two adjacent metal shunt electrodes 212, 213. A first anode layer 321 and a second anode layer 322 separated from each other are disposed above the metal shunt electrodes 212, 213, respectively, and above insulating layers 214, 215, respectively. An organic semiconductor layer 230 is disposed to cover the insulating layers 214, 215, 216 and the first anode layer 321 and the second anode layer 322e. A cathode layer 240 is disposed to cover the organic semiconductor layer 230.

FIG. 4B is a top view showing the OLED device shown in FIG. 4A. The plurality of metal shunt electrodes 212, 213 shown in FIGS. 4A and 4B are for transmitting a main current. An anode layer contacting with the metal shunt electrodes 212, 213 is divided into the first anode layer 321 and the second anode layer 322 separated from each other so that a current transmitted in each metal shunt electrode 212, 213 can be reduced.

In summary, according to the invention, a step coverage of the organic semiconductor layer is increased by designing a relative thickness ratio of the anode layer and the organic semiconductor layer. In this way, the edge leakage problem can be prevented and a conventional bank structure in an OLED device can be omitted. This improves an element yield rate and increases a light-emitting area of the OLED device. Moreover, according to the invention, short-circuit caused by an impurity adhered to the substrate in the manufacturing process can be prevented by designing an interval between two adjacent anode layers. Therefore, according to the invention, not only the process for manufacturing an OLED device used in a lighting apparatus can be simplified, but also the element yield rate can be increased, and a light-emitting efficiency of an OLED lighting apparatus can be improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An organic light-emitting diode (OLED) device, comprising:
a substrate;
a patterned anode layer disposed on the substrate;
an organic semiconductor layer disposed to cover an upper surface and sidewalls of the patterned anode layer and the substrate, wherein a thickness of the organic semiconductor layer is greater than three times of that of the patterned anode layer; and
a cathode layer disposed to cover the organic semiconductor layer.

2. The OLED device as claimed in claim 1, wherein the patterned anode layer comprises a first anode layer and a second anode layer disposed on the substrate side by side, and the organic semiconductor layer also covers a substrate surface between the first anode layer and the second anode layer.

3. The OLED device as claimed in claim 2, wherein an interval between the first anode layer and the second anode layer is greater than 3 μm.

4. The OLED device as claimed in claim 2, wherein an interval between the first anode layer and the second anode layer is between 3˜10 μm.

5. The OLED device as claimed in claim 1, wherein a thickness of the organic semiconductor layer is between 150˜300 nm, and a thickness of the patterned anode layer is between 40˜60 nm.

6. The OLED device as claimed in claim 1, wherein the OLED device is used in a lighting apparatus.

7. The OLED device as claimed in claim 1, wherein the organic semiconductor layer comprises at least a hole injection layer, a hole transport layer, a light-emitting layer, an electron transport layer and an electron injection layer.

8. The OLED device as claimed in claim 1, wherein the patterned anode layer is a transparent conductive layer.

9. The OLED device as claimed in claim 1, wherein the substrate is a transparent substrate.
